(19) United States
(12) Patent Application Publication
(10) Pub. No.: US 2017/0005672 A1
(43) Pub. Date: Jan. 5, 2017

(54) PARTIAL PARITY ECC CHECKING MECHANISM WITH MULTI-BIT HARD AND SOFT ERROR CORRECTION CAPABILITY

(71) Applicant: Samsung Electronics Co., Ltd., Suwon-si (KR)

(72) Inventor: John H. HUGHES, JR., Morgan Hill, CA (US)

(21) Appl. No.: 14/789,887

(22) Filed: Jul. 1, 2015

(51) Int. Cl. H03M 13/15; G11C 29/52; H03M 13/00; G06F 11/10

(52) U.S. Cl. CPC H03M 13/1575; G06F 11/1068; G11C 29/52; H03M 13/617

(57) ABSTRACT

Embodiments of the inventive concept include a system and method for computing a partial parity error correcting code. Check bits are computed from subsets of the data bits and stored. When the data bits are read, the check bits can be recomputed from the read data bits and compared with the stored check bits to generate a syndrome value. The syndrome value can identify which data bits and/or check bits are in error and correct for the errors.

### FIELD

The invention pertains to error correction, and more particularly to error correcting codes that can handle multiple-bit errors.

### BACKGROUND

The use of error correcting codes to correct Random Access Memory (RAM) soft errors using a single-error correcting/double-error detecting (SEC/DED) Hamming code is well known. The soft errors (SEUs) can be caused by high energy particles causing a random bit to change value. The SEC/DED correction method depends on the fact that SEUs have a very low rate of occurrence and rarely cause more than one bit error in a single RAM word. This last condition is aided by a feature of RAM design that places physically proximate RAM cells in different RAM words.

A second cause of RAM errors is manufacturing faults that have an entirely different characteristic. These faults can manifest as hard faults that cause a RAM bit to always read as a 0 (SA-0) or 1 (SA-1). These stuck-at faults are considered classical faults. There are also failures due to parametric, leakage, or bridging faults. These types of faults are considered non-classical because they do not present a persistent (“hard”) presence, but can be data- or operating point-dependent.

While an SEC/DED Hamming code is useful, it has its limitations. It can only detect two-bit or less-bit errors, and can only correct a single bit error. In other words, if there are three or more errors in the combination of the data and the parity codes, the Hamming code cannot reliably identify the errors. Even if there are only two errors in the combination of the data and the parity codes, the Hamming code can only detect this situation: it cannot correct it.

A need remains for a way to generate error correcting codes that can identify and correct for any number of bit errors.

### BRIEF DESCRIPTION OF THE DRAWINGS

FIG. 1 shows a circuit that can be used to generate a correction vector for multi-bit errors, according to an embodiment of the inventive concept.

FIG. 2 shows an example of a set of check-bits that can be used to correct for double-bit errors in 32-bit data in the circuit of FIG. 1.

FIG. 3 shows a mapping of different syndrome values to different error conditions in the circuit of FIG. 1.

FIG. 4 shows a computer system that can include the circuit of FIG. 1 to correct for multi-bit errors.

FIG. 5 shows a flowchart of a procedure to use an error correcting code that can correct for multi-bit errors in data, according to an embodiment of the inventive concept.

FIG. 6 shows a flowchart of a procedure for generating check bits in the flowchart of FIG. 5.

FIG. 7 shows a flowchart of a procedure for correcting an error in the flowchart of FIG. 5.

### DETAILED DESCRIPTION

Embodiments of the inventive concept idea use a set of partial parity check bits to produce a unique check word that can be stored with the data. The check bits are computed such that any number of bit errors in the data bits, the check bits, or a combination of the data and check bits that is less than or equal to the correction capacity of the check code will produce a data/check bit combination that will result in another unique code based on a re-computation of check bits from the possibly faulty data word. If the recomputed check bits are XORed with the check bits (with possible faults) that were read, a syndrome value of the same width can be produced. The syndrome can identify which bits are in error.

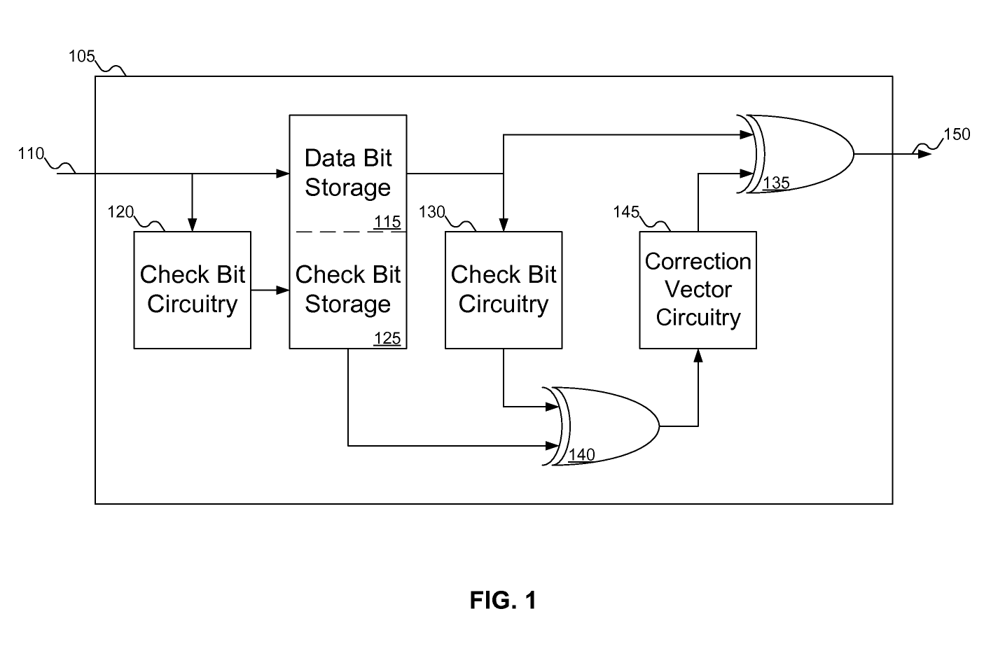

FIG. 1 shows a module that can be used to generate a correction vector for multi-bit errors, according to an embodiment of the inventive concept. FIG. 1 will be discussed first at a high level, and then with more specific discussion about certain elements. Module 105 can be used in any desired element(s) of a computer, but for exemplary purposes, module 105 is shown as a memory module, such as can be used in Random Access Memory (RAM). Module 105 does not show control inputs, such as a line for indicating whether data is to be read or written. In addition, module 105 can be generalized to any desired memory configuration, including data that can be read or written in parallel, among other possibilities.

In FIG. 1, data is input for writing via line 110. The data is fed into two elements: data storage 115 and check bit circuitry 120. Check bit circuitry 120 can be used to generate the check bits used in the error correcting code in embodiments of the inventive concept. The check bits generated by check bit circuitry 120 can be stored in check bit storage 125. Check bit storage 125 is part of the storage of the module: either module 105 can be expanded with additional storage for check bit storage 125, or check bit storage 125 can be taken from data storage 115 (with a concordant reduction in the capacity of data storage 115). In addition, while FIG. 1 shows data storage 115 and distinct from check bit storage 125, the check bits can be stored intermixed with the data bits, within a single storage element. All that matters is that the check bits can be processed as check bits, rather than as data bits.

When it is time to read the data, the data from data storage 115 is accessed. The read data is fed into two elements: check bit circuitry 130 and XOR gate 135. Check bit circuitry 130 generates check bits using the same logic as check bit circuitry 120. In some embodiments of the inventive concept, check bit circuitry 120 can be used to generate the check bits after data is read from data storage 115, reducing the amount of circuitry needed in module 105.

The check bits can read from check bit storage 125. The check bits can be read from check bit storage 125 in parallel with the data bits from data storage 115, or the timing can be adjusted as appropriate: for example, to ensure that all the inputs to XOR gate 140 arrive at the same time. The check bits, as read from check bit storage 125 and as generated by check bit circuitry 130, are input to XOR gate 140. XOR gate 140 then computes a bitwise XOR on the two input sets of check bits. More specifically, XOR gate 140 computes an XOR on the two bits C₀, the two bits C₁, and so on for each bitwise pair of check bits.

By XORing individual pairs of check bits, module 105 can determine whether any individual pairwise check bits do not agree. If a pair of check bits agrees, the result of XOR gate 140 for those pair of check bits will be 0; if a pair of check bits does not agree, then the result of XOR gate 140 will be 1. The advantage of computing XOR operations on pairs of check bits is that the comparison can be used to identify the type of error and correct for it, and is discussed further below.

The result of XOR gate 140, when taken as a sequence of bits, can be termed a syndrome. A syndrome is therefore a bit pattern that can identify what errors have occurred (up to the limits of the error correcting code). That is, a syndrome can identify whether there are 1, 2, 3 . . . up to E bit errors between the data bits and the check bits, and which bits are in error. Further, the syndrome can be used to generate a correction vector that can be used to correct for the detected errors. Correction vector circuitry 145 takes the syndrome output by XOR gate 140, and generates the appropriate correction vector for the data bits. This correction vector is then input to XOR gate 135 (along with the data bits read from data storage 115). The result of XOR gate 135 is then the correct data, which can be output from module 105 via line 150.

Examining FIG. 1 in more detail, some additional discussion about check bit circuitry 120 and 130, the calculation of the syndrome by XOR gate 140, and correction vector circuitry 145, is warranted. First, as discussed above, check bit circuitry 120 and 130 can generate the check bits used in the error correction code. The specifics of how check bit circuitry 120 and 130 can generate the check bits depend on the specifics of the error correcting code being used. The number of data bits being encoded and the number of bit errors the code is designed to correct are variables that affect how many check bits are needed. If C represents the number of check bits used in the error correcting codes, D represents the number of data bits being encoded, and E represents the number maximum number of correctable errors, then C is bounded from below by the following two equations:

C=E*N

2^{N}>=(D+C+1)

Note that all the variables in this set of equations need to be positive integers. Also, the number of check bits needed in the error correcting code is bounded from above only by the amount of storage available.

For data of a given size D and a maximum number of correctable errors E, there can be multiple different check bit combinations that will provide the error correcting capability. Each check bit can be generated as an XOR of a fractional subset of the data bits. To be able to detect and correct errors in the data bits, each data bit needs to be included in some subset of the check bits, and each check bit needs to include a different subset of the data bits. In addition, each unique value represented by the data bits needs to result in a unique combination of check bit values. Any check bit calculation that satisfies these constraints could theoretically be used to produce the desired error correcting code.

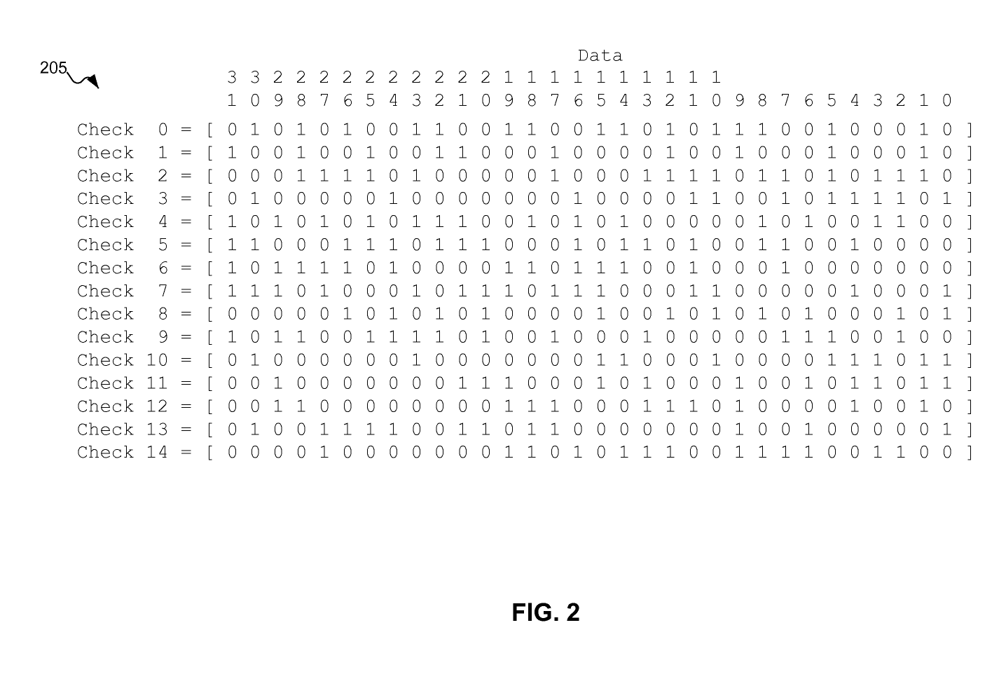

An example of an error correcting code that can correct up to two bit errors over 32-bit data is shown in FIG. 2. In FIG. 2, 15 check bit vectors 205 are shown. Each check bit is calculated as the XOR of the data bits for which the check bit has a 1 in the corresponding coordinate. Thus, for example, check bit 0 computes an XOR of data bits 1, 5, 8, 9, 10, 12, 14, 15, 18, 19, 22, 23, 26, 28, and 30, check bit 1 computes an XOR of data bits 1, 5, 9, 12, 17, 21, 22, 25, 28, and 31, and so on. Note that each check bit computes an XOR of a different subset of the data bits, and each data bit is included in at least one check bit computation. Given this description of how to calculate the check bits, it is easy to design circuitry for check bit circuitry 120 and 130 of FIG. 1 that computes the check bits.

It is worth noting that when D=32 and E=2, the minimum value for C that satisfies the equations above is C=12. Thus, check bits 205 not only represent one possible set of check bits, but it does not necessarily represent a minimum set of check bits that can provide the desired error correcting capability.

As can be seen from FIG. 2, the data bits can be used in computing any number of check bits: that is, there is no requirement that the individual data bits be used the same number of times across the check bits. Nor do the check bits need to use the same number of data bits: that is, different number of data bits can be used in computing different check bits. In fact, any regularity in the check bit calculation is likely to cause the coding pattern to be unusable.

In addition to the partial parity check bits, an additional full parity check bit can be computed as an XOR of all the data bits. The full parity check bit can be used to correlate the error count from the syndrome value since a full parity check is equivalent to the number of errors modulo 2. But a full parity check bit is not needed with a partial parity error correcting code because the syndrome space is more sparsely filled in the partial parity method, so there is better inherent uncorrectable error detection.

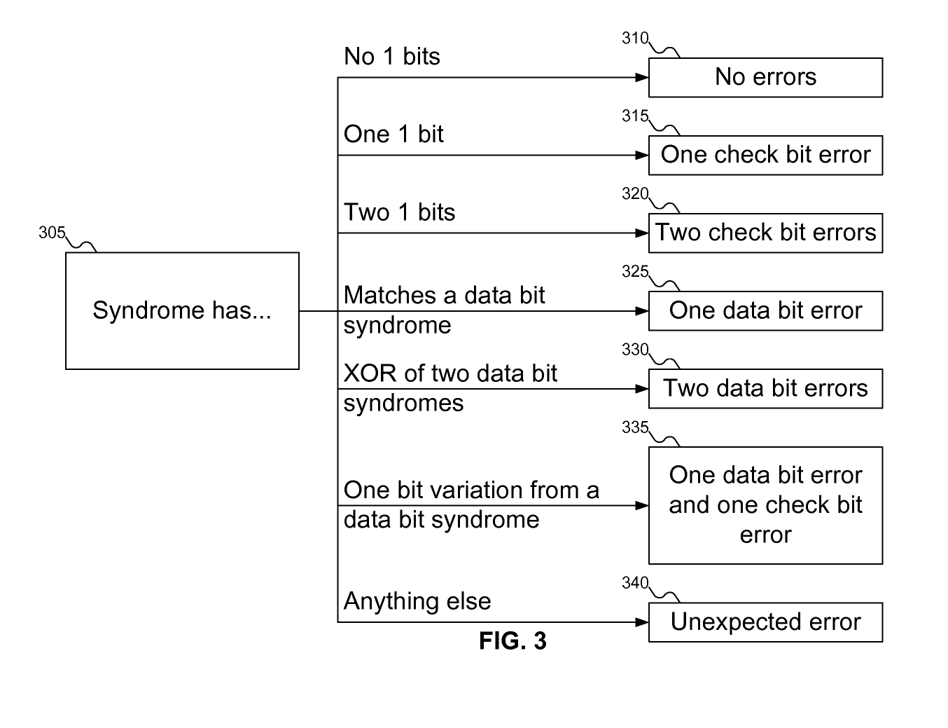

Returning to FIG. 1 and turning to the generation of the syndrome value, as discussed above, the syndrome value is computed as the XOR of the check bits as computed by check bit circuitry 130 and as read from check bit storage 125. If there are C check bits used in the error correcting code, then there are 2^{C} possible values for the syndrome. But most of these values are unlikely to occur. That is, the number of syndrome values that are meaningful is small relative to the space of all possible syndrome values. FIG. 3 shows a mapping of different syndrome values to different error conditions in the circuit of FIG. 1.

FIG. 3 shows an example mapping for different syndrome values to different error conditions using an error correcting code that can correct for up to two bit errors. But the mapping shown in FIG. 3 can be generalized to handle any number of bit errors. As shown in FIG. 3, if syndrome 305 has no bits set to 1, that means that the check bits as read from check bit storage 125 matched the check bits computed by check bit circuitry 130. Since the check bits matched, there were no errors in the data, as shown as result 310. If syndrome 305 has one bit set to 1, then there was an error in a single check bit, as shown in result 315. Similarly, if syndrome 305 has two bits set to 1, then there were two check bit errors, as shown in result 320. (The technique used to generate the check bits in check bit circuitry 120 and 130 guarantees that a syndrome cannot have either one or two bits set to 1 due to any combination of data bit errors—at least, within the tolerance of the error correcting code.)

There are specific patterns that will occur in syndrome 305 if exactly one data bit, as read from data storage 115, differs from the data bits input to module 105 via line 110. These patterns can be generated in advance and stored (for example, within correction vector circuitry 145), and can be compared against syndrome 305. Thus, if syndrome 305 has a bit pattern that matches a pattern indicating a single bit error, then there is a single data bit error, as shown in result 325. In addition, if exactly two data bits, as read from data storage 115, differ from the data bits input to module 105 via line 110, then syndrome 305 will match an XOR of two bit patterns indicating those single bit errors. Thus, if syndrome 305 matches an XOR of two bit patterns indicating single bit errors, then there is a double data bit error, as shown in result 330. As with the single data bit error, the XOR of all possible pairs of single data bit errors can be generated in advance and stored, to make the comparison against syndrome 305 simpler and faster.

If there are two errors, one in a data bit and one in a check bit, then the result is a syndrome that differs from a single data bit error in one bit. Note that this one bit difference can be either a bit set to 1 (that is, a check bit that should not have been set but was) or a bit set to 0 (that is, a check bit that should have been set but was not). If syndrome 305 has a pattern that matches a single data bit error but for one check bit, then there is both a single data bit error and a single check bit error, as shown by result 335. As with the patterns for data bit errors, these patterns that combine a data bit and a check bit error can be generated in advance and stored.

Finally, it might happen that the syndrome does not match any of the patterns described above. If this situation occurs, then there has been an unexpected error, as shown in result 340. An example of such an unexpected error is where the number of bits in error exceeds the correction capacity of the code. An unexpected error can be handled in any desired manner (such as throwing an exception), since the error correcting code cannot correct for the error.

As an example of possible syndrome values and their meanings, consider the check bits generated using FIG. 2. If the expected and read check bits are the same, then the syndrome value is an all 0 value. If the 15 bit syndrome value is expressed as a hexadecimal number (using [14:0]), the value 0x2D88 indicates that there was an error reading data bit 0, as only the check bits that include data bit 0 are set (specifically, check bits 3, 7, 8, 10, 11, and 13). On the other hand if the syndrome value is 0x11C6 there were errors in both data bit 1 and data bit 15, as check bits 1, 2, 6, 7, 8, and 12 are the only check bits that include one or the other (but not both) of data bits 1 and 15.

This syndrome to error position table can be pre-computed once a check bit mapping solution is known. Check bit errors are easily identified since they are simple powers of 2: 0x0001 is check bit 0, 0x0002 is check bit 1, and so on. Similarly, all double check bit errors will map to syndrome values that have only two 1 bits, with each being a check bit pointer based on the “power of 2” rule for single check bit errors. Errors that are a combination of a data bit and a check bit are the data bit syndrome XORed with and additional “power of 2” check bit syndrome.

As discussed above, one property of syndrome 305 is that the number of syndrome values that identify errors is small relative to the space of all possible syndrome values. Specifically, if there are C check bits, there is only one possible syndrome value that indicates no errors; there are C possible syndrome values that indicate a single bit error (of either a data bit or a check bit), there are C·(C−1) possible syndrome values that indicate two check bit errors or two data bit errors, and C² possible syndrome values that indicate one data bit error and one check bit error. Thus, the total of all meaningful syndrome values is 3C²+1 out of the 2^{C} possible syndrome values. Of course, if the number of check bits is kept constant and the error correcting code is designed to correct more than two bit errors, a greater percentage of possible syndrome values are meaningful, but even so, the percentage of meaningful syndrome values remains small relative to the space including all possible syndrome values.

A few consequences of the interpretation of the syndrome value, as shown in FIG. 3, can be inferred. First, note that a syndrome value will have a bit set to 1 for each check bit that is incorrectly read from check bit storage 125. Therefore, any syndrome value that identifies a data bit error has more than this number of bits set to 1. So, if the error correcting code is designed to correct up to E bit errors, then the number of bits set to 1 in a syndrome identifying a data bit error has at least E+1 bits set to 1. Put another way, if a syndrome value identifying a data bit error were to have no more than E bits set to 1, the syndrome could not distinguish between the data bit error and a set of check bit errors.

A second consequence of the interpretation of the syndrome value is that any data bit is used in at least E different check bits. The reason is simple. Assume that a data bit were used in only 1 check bit (this assumption reduces the scenario to a trivial case for understanding, but can be generalized to any number of check bits that is fewer than E). If that data bit were read incorrectly from data bit storage 115, then only one check bit would be set to 1. The syndrome value would then not be able to distinguish between the data bit being read incorrectly or that check bit being read incorrectly.

Turning to correction vector circuitry 145, as discussed above, correction vector circuitry 145 takes a syndrome and generates an appropriate correction vector to correct for bit errors. Since each syndrome is a unique fault identifier, a correction vector that identifies the bit or bits to be corrected can be produced from a simple AND-OR structure using just the syndrome bits. That is, all syndrome values that map to a particular correction vector can be ANDed together, and all the possible resulting correction vectors can be ORed together, returning the appropriate correction vector for a particular syndrome value. Note that while each meaningful syndrome value represents a different error condition, different syndrome values can result in the same correction vector. For example, check bit errors, while important to catch, do not need to be corrected as part of reading the data, since the application only needs the data bits. Thus, for example, a syndrome value that identifies an error in data bit 1 and syndrome values that identify errors in both data bit 1 and any check bit can map to the same correction vector.

Other error correcting codes exist. But using embodiments of the inventive concept has advantages over such error correcting codes. Embodiments of the inventive concept are capable of correcting multiple data faults, such as might occur if there was a SEU soft error in a word along with a hard manufacturing fault. In addition, embodiments of the inventive concept include a much simpler implementation structure. For example, a BCH(63,51,5) code can correct up to 2 errors in a 32 bit data word using a 12 bit check word. But such a code requires 32 levels of XOR gating (assuming that the other 31 extra code bits are bypassed) for the check bit generation and syndrome computation. Further, once the syndrome has been computed, there remains a multiple level computation to derive the error locations. In contrast, embodiments of the inventive concept allow the check bits to be computed in parallel and the error locations to be directly mapped, making embodiments of the inventive concept more appropriate for situations with high speed timing constraints, such as a RAM application.

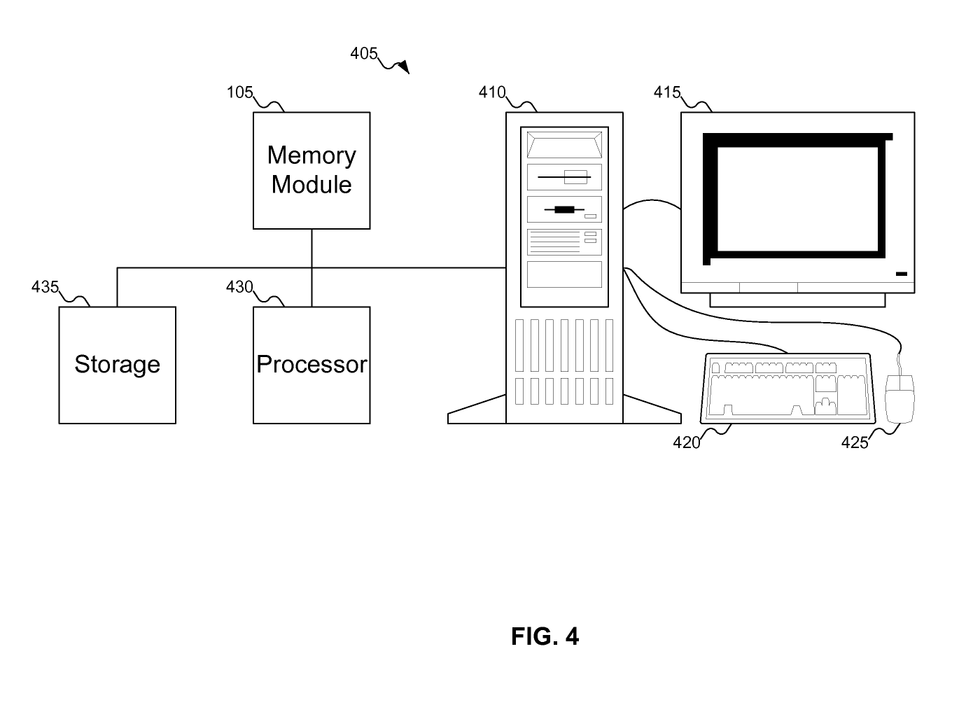

FIG. 4 shows a computer system that can include the circuit of FIG. 1 to correct for multi-bit errors. In FIG. 4, computer system 405 is shown as including computer 410, monitor 415, keyboard 420, and mouse 425. A person skilled in the art will recognize that other components can be included with computer system 405: for example, other input/output devices, such as a printer. In addition, in FIG. 4, computer system 405 can include conventional internal components, such as central processing unit 430 or storage 435. Although not shown in FIG. 4, a person skilled in the art will recognize that computer system 405 can interact with other computer systems, either directly or over a network (not shown) of any type. Finally, although FIG. 4 shows computer system 405 as a conventional desktop computer, a person skilled in the art will recognize that computer system 405 can be any type of machine or computing device capable of providing the services attributed herein to computer system 405, including, for example, a laptop computer, a tablet computer, a personal digital assistant (PDA), or a smart phone, among other possibilities.

Where embodiments of the inventive concept are implemented in a memory module, such as memory module 105, memory module 105 can be included in computer system 405. But embodiments of the inventive concept can be implemented in other types of modules, which could also be included in computer system 405 or other applicable machines.

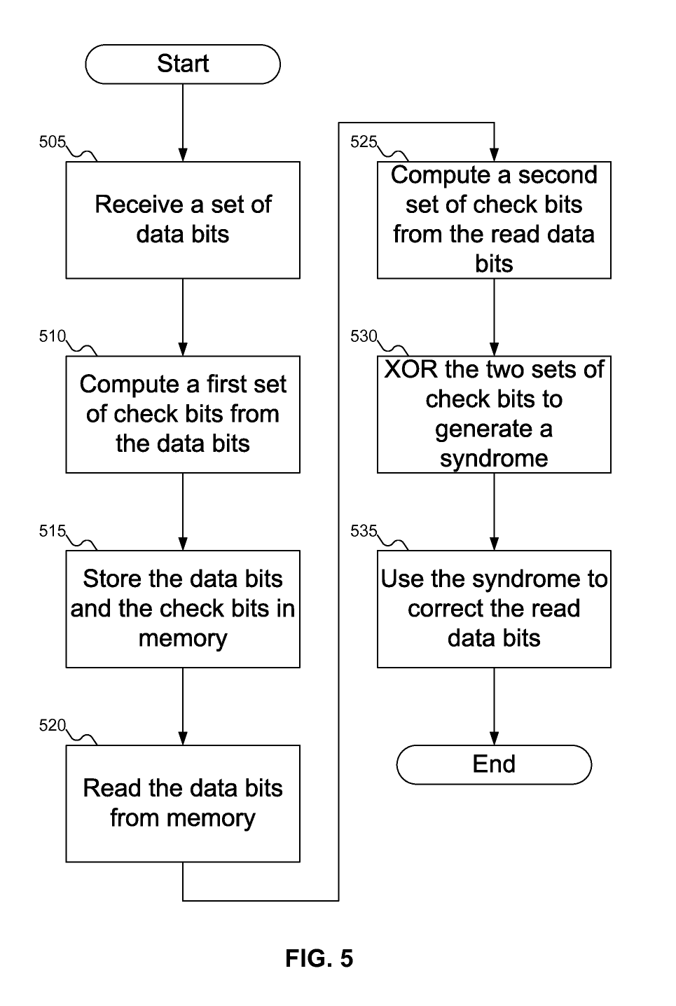

FIG. 5 shows a flowchart of a procedure to use an error correcting code that can correct for multi-bit errors in data, according to an embodiment of the inventive concept. In FIG. 5, at block 505, the system receives a set of data bits. At block 510, the system computes a first set of check bits based on the received data bits. At block 515, the system stores the data bits and the computed check bits. At block 520, the system reads the data bits. At block 525, the system computes a second set of check bits. At block 530, the system performs an XOR operation on the two sets of check bits, producing a syndrome value. A block 535, the system then can use the syndrome value to generate a correction vector that can be applied to the read data bits, correcting the output.

In FIG. 5 (and in the other flowcharts below), one embodiment of the inventive concept is shown. But a person skilled in the art will recognize that other embodiments of the inventive concept are also possible, by changing the order of the blocks, by omitting blocks, or by including links not shown in the drawings. All such variations of the flowcharts are considered to be embodiments of the inventive concept, whether expressly described or not.

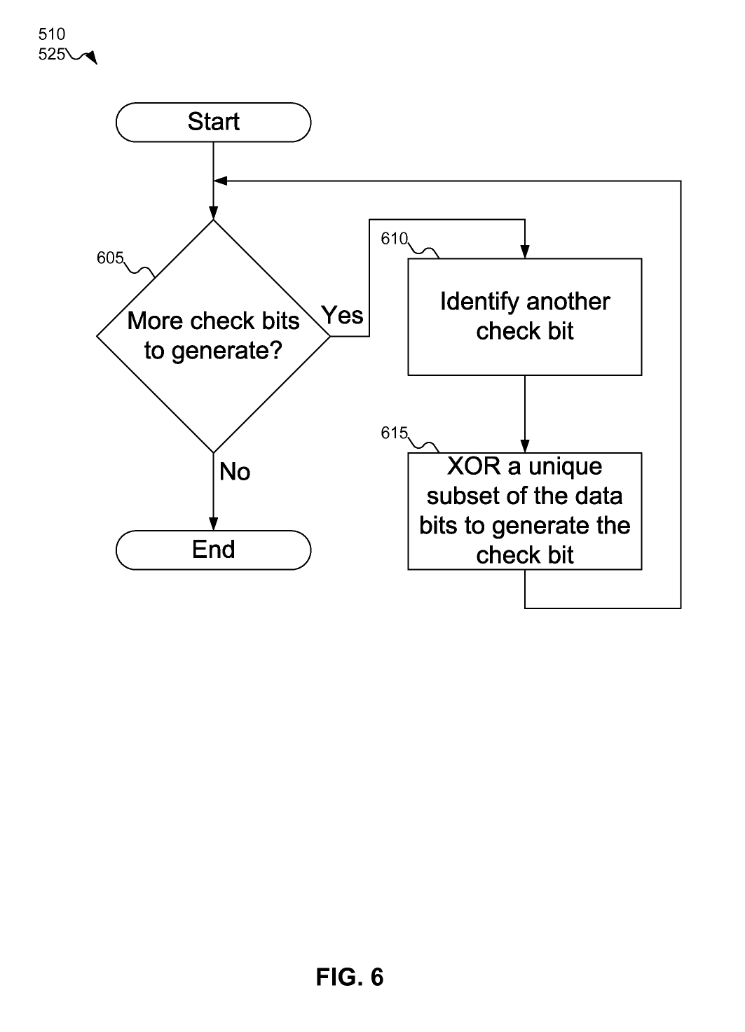

FIG. 6 shows a flowchart of a procedure for generating check bits in the flowchart of FIG. 5. At block 605, the system determines if there are more check bits to generate. If not, then processing ends. But if there are more check bits to generate, then at block 610 the system identifies another check bit, and at block 615 the system performs an XOR operation on a unique subset of the data bits to generate the check bit. Control then returns to block 605.

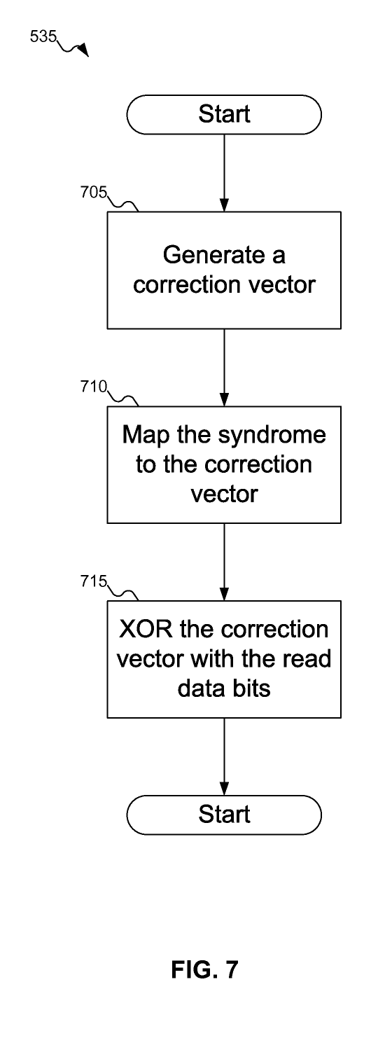

FIG. 7 shows a flowchart of a procedure for correcting an error in the flowchart of FIG. 5. At block 705, the system generates a correction vector. As described above, the correction vector can be generated by mapping the syndrome value to a particular correction vector, as shown in block 710. Then, at block 715 the system can perform an XOR operation on the read data bits and the correction vector, to correct any errors in the read data bits.

The following discussion is intended to provide a brief, general description of a suitable machine or machines in which certain aspects of the inventive concept can be implemented. Typically, the machine or machines include a system bus to which is attached processors, memory, e.g., random access memory (RAM), read-only memory (ROM), or other state preserving medium, storage devices, a video interface, and input/output interface ports. The machine or machines can be controlled, at least in part, by input from conventional input devices, such as keyboards, mice, etc., as well as by directives received from another machine, interaction with a virtual reality (VR) environment, biometric feedback, or other input signal. As used herein, the term “machine” is intended to broadly encompass a single machine, a virtual machine, or a system of communicatively coupled machines, virtual machines, or devices operating together. Exemplary machines include computing devices such as personal computers, workstations, servers, portable computers, handheld devices, telephones, tablets, etc., as well as transportation devices, such as private or public transportation, e.g., automobiles, trains, cabs, etc.

The machine or machines can include embedded controllers, such as programmable or non-programmable logic devices or arrays, Application Specific Integrated Circuits (ASICs), embedded computers, smart cards, and the like. The machine or machines can utilize one or more connections to one or more remote machines, such as through a network interface, modem, or other communicative coupling. Machines can be interconnected by way of a physical and/or logical network, such as an intranet, the Internet, local area networks, wide area networks, etc. One skilled in the art will appreciate that network communication can utilize various wired and/or wireless short range or long range carriers and protocols, including radio frequency (RF), satellite, microwave, Institute of Electrical and Electronics Engineers (IEEE) 802.11, Bluetooth®, optical, infrared, cable, laser, etc.

Embodiments of the present inventive concept can be described by reference to or in conjunction with associated data including functions, procedures, data structures, application programs, etc. which when accessed by a machine results in the machine performing tasks or defining abstract data types or low-level hardware contexts. Associated data can be stored in, for example, the volatile and/or non-volatile memory, e.g., RAM, ROM, etc., or in other storage devices and their associated storage media, including hard-drives, floppy-disks, optical storage, tapes, flash memory, memory sticks, digital video disks, biological storage, etc. Associated data can be delivered over transmission environments, including the physical and/or logical network, in the form of packets, serial data, parallel data, propagated signals, etc., and can be used in a compressed or encrypted format. Associated data can be used in a distributed environment, and stored locally and/or remotely for machine access.

Embodiments of the inventive concept can include a tangible, non-transitory machine-readable medium comprising instructions executable by one or more processors, the instructions comprising instructions to perform the elements of the inventive concepts as described herein.

Having described and illustrated the principles of the inventive concept with reference to illustrated embodiments, it will be recognized that the illustrated embodiments can be modified in arrangement and detail without departing from such principles, and can be combined in any desired manner. And, although the foregoing discussion has focused on particular embodiments, other configurations are contemplated. In particular, even though expressions such as “according to an embodiment of the inventive concept” or the like are used herein, these phrases are meant to generally reference embodiment possibilities, and are not intended to limit the inventive concept to particular embodiment configurations. As used herein, these terms can reference the same or different embodiments that are combinable into other embodiments.

The foregoing illustrative embodiments are not to be construed as limiting the inventive concept thereof. Although a few embodiments have been described, those skilled in the art will readily appreciate that many modifications are possible to those embodiments without materially departing from the novel teachings and advantages of the present disclosure. Accordingly, all such modifications are intended to be included within the scope of this inventive concept as defined in the claims.

Embodiments of the inventive concept can extend to the following statements, without limitation:

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying and correcting at least two bit errors.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying and correcting at least two bit errors and the syndrome includes at least E bits set to 1 if at least one data bit is read from the memory incorrectly, where E is greater than the number of bits the method is intended to correct.

An embodiment of the inventive concept includes a memory module, comprising: storage for data bits; storage for check bits; check bit circuitry to compute the check bits from the data bits using XOR gates on unique subsets of the data bits; and an XOR gate to compute a syndrome from the check bits, wherein the syndrome is capable of identifying and correcting at least two bit errors.

An embodiment of the inventive concept includes a memory module, comprising: storage for data bits; storage for check bits; check bit circuitry to compute the check bits from the data bits using XOR gates on unique subsets of the data bits; and an XOR gate to compute a syndrome from the check bits, wherein the syndrome is capable of identifying and correcting at least two bit errors, and wherein each of the data bits is used in at least E of the first set of partial parity check bits, where E is greater than a number of bit errors the method is intended to correct.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying and correcting at least two bit errors among the following results: no errors, one data bit error, one check bit error, one data bit err and one check bit error, two data bit errors, and two check bit errors.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying a one check bit error when the syndrome includes exactly one bit set to 1.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying a two check bit error when the syndrome includes exactly two bits set to 1.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying a one bit data error at data bit b if a bit in the syndrome is set to 1 if and only if data bit b is used in computing a corresponding check bit.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying a two bit data error at data bits b₁ and b₂ if a bit in the syndrome is set to 1 if and only if one of data bits b₁ and b₂ are used in computing a corresponding check bit.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying both a data bit error at data bit b and a check bit error if the syndrome is an XOR of a second syndrome in which a bit in the syndrome is set to 1 if and only if data bit b is used in computing a corresponding check bit and a third syndrome including exactly one bit set to 1.

An embodiment of the inventive concept includes a memory module, comprising: storage for data bits; storage for check bits; check bit circuitry to compute the check bits from the data bits; and an XOR gate to compute a syndrome from the check bits, wherein the syndrome is capable of identifying there are no errors in the data bits if no bit in the syndrome is set to 1.

An embodiment of the inventive concept includes a memory module, comprising: storage for data bits; storage for check bits; check bit circuitry to compute the check bits from the data bits; an XOR gate to compute a syndrome from the check bits; correction vector circuitry to generate a correction vector from the syndrome vector; and a second XOR gate to correct the data bits, wherein the syndrome is capable of identifying and correcting at least two bit errors.

An embodiment of the inventive concept includes a memory module, comprising: storage for data bits; storage for check bits; check bit circuitry to compute the check bits from the data bits; an XOR gate to compute a syndrome from the check bits; correction vector circuitry including a two-level logic gate structure to generate a correction vector from the syndrome vector; and a second XOR gate to correct the data bits, wherein the syndrome is capable of identifying and correcting at least two bit errors.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying and correcting at least two bit errors.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying and correcting at least two bit errors and the syndrome includes at least E bits set to 1 if at least one data bit is read from the memory incorrectly, where E is greater than the number of bits the method is intended to correct.

An embodiment of the inventive concept includes a system, comprising: a computer; a memory in the computer, the memory including: storage for data bits; storage for check bits; check bit circuitry to compute the check bits from the data bits using XOR gates on unique subsets of the data bits; and an XOR gate to compute a syndrome from the check bits, wherein the syndrome is capable of identifying and correcting at least two bit errors.

An embodiment of the inventive concept includes a system, comprising: a computer; a memory in the computer, the memory including: storage for data bits; storage for check bits; check bit circuitry to compute the check bits from the data bits using XOR gates on unique subsets of the data bits; and an XOR gate to compute a syndrome from the check bits, wherein the syndrome is capable of identifying and correcting at least two bit errors, and wherein each of the data bits is used in at least E of the first set of partial parity check bits, where E is greater than a number of bit errors the method is intended to correct.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying and correcting at least two bit errors among the following results: no errors, one data bit error, one check bit error, one data bit err and one check bit error, two data bit errors, and two check bit errors.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying a one check bit error when the syndrome includes exactly one bit set to 1.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying a two check bit error when the syndrome includes exactly two bits set to 1.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying a one bit data error at data bit b if a bit in the syndrome is set to 1 if and only if data bit b is used in computing a corresponding check bit.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying a two bit data error at data bits b₁ and b₂ if a bit in the syndrome is set to 1 if and only if one of data bits b₁ and b₂ are used in computing a corresponding check bit.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying both a data bit error at data bit b and a check bit error if the syndrome is an XOR of a second syndrome in which a bit in the syndrome is set to 1 if and only if data bit b is used in computing a corresponding check bit and a third syndrome including exactly one bit set to 1.

An embodiment of the inventive concept includes a system, comprising: a computer; a memory in the computer, the memory including: storage for data bits; storage for check bits; check bit circuitry to compute the check bits from the data bits; and an XOR gate to compute a syndrome from the check bits, wherein the syndrome is capable of identifying there are no errors in the data bits if no bit in the syndrome is set to 1.

An embodiment of the inventive concept includes a system, comprising: a computer; a memory in the computer, the memory including: storage for data bits; storage for check bits; check bit circuitry to compute the check bits from the data bits; an XOR gate to compute a syndrome from the check bits; correction vector circuitry to generate a correction vector from the syndrome vector; and a second XOR gate to correct the data bits, wherein the syndrome is capable of identifying and correcting at least two bit errors.

An embodiment of the inventive concept includes a system, comprising: a computer; a memory in the computer, the memory including: storage for data bits; storage for check bits; check bit circuitry to compute the check bits from the data bits; an XOR gate to compute a syndrome from the check bits; correction vector circuitry including a two-level logic gate structure to generate a correction vector from the syndrome vector; and a second XOR gate to correct the data bits, wherein the syndrome is capable of identifying and correcting at least two bit errors.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying and correcting at least two bit errors.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying and correcting at least two bit errors and wherein the syndrome includes at least E bits set to 1 if at least one data bit is read from the memory incorrectly, where E is greater than the number of bits the method is intended to correct.

An embodiment of the inventive concept includes a method for performing partial parity error correction, comprising: receiving a set of data bits; computing, using check bit circuitry, a first set of partial parity check bits using the data bits including XORing a unique subset of the data bits to compute each of the first set of partial parity check bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying and correcting at least two bit errors.

An embodiment of the inventive concept includes a method for performing partial parity error correction, comprising: receiving a set of data bits; computing, using check bit circuitry, a first set of partial parity check bits using the data bits including XORing a unique subset of the data bits to compute each of the first set of partial parity check bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying and correcting at least two bit errors, and wherein each of the data bits is used in at least E of the first set of partial parity check bits, where E is greater than a number of bit errors the method is intended to correct.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying and correcting at least two bit errors among the following results: no errors, one data bit error, one check bit error, one data bit err and one check bit error, two data bit errors, and two check bit errors.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying a one check bit error when the syndrome includes exactly one bit set to 1.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying a two check bit error when the syndrome includes exactly two bits set to 1.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying a one bit data error at data bit b if a bit in the syndrome is set to 1 if and only if data bit b is used in computing a corresponding check bit.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying a two bit data error at data bits b₁ and b₂ if a bit in the syndrome is set to 1 if and only if one of data bits b₁ and b₂ are used in computing a corresponding check bit.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying both a data bit error at data bit b and a check bit error if the syndrome is an XOR of a second syndrome in which a bit in the syndrome is set to 1 if and only if data bit b is used in computing a corresponding check bit and a third syndrome including exactly one bit set to 1.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors, wherein the syndrome is capable of identifying there are no errors in the data bits if no bit in the syndrome is set to 1.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors including generating a correction vector from the syndrome vector and XORing the data bits with the correction vector, wherein the syndrome is capable of identifying and correcting at least two bit errors.

An embodiment of the inventive concept includes a method for performing partial parity error correction, comprising: receiving a set of data bits; computing, using check bit circuitry, a first set of partial parity check bits using the data bits; storing the data bits and the partial parity check bits in memory; reading the data bits from the memory; computing a second set of partial parity check bits using the read data bits; XORing the first set of partial parity check bits with the second set of partial parity check bits to produce a syndrome; and using the syndrome to correct any bit errors including mapping the syndrome value to a correction vector from the syndrome vector in a two-level logic gate structure and XORing the data bits with the correction vector, wherein the syndrome is capable of identifying and correcting at least two bit errors.

Consequently, in view of the wide variety of permutations to the embodiments described herein, this detailed description and accompanying material is intended to be illustrative only, and should not be taken as limiting the scope of the inventive concept. What is claimed as the inventive concept, therefore, is all such modifications as may come within the scope and spirit of the following claims and equivalents thereto.

What is claimed is:

1. A memory module (105), comprising:
storage (115) for data bits;
storage (125) for check bits;
check bit circuitry (120, 130) to compute the check bits from the data bits; and
an XOR gate (140) to compute a syndrome from the check bits,
wherein the syndrome is capable of identifying and correcting at least two bit errors.

2. A memory module (105) according to claim 1, wherein the syndrome includes at least E bits set to 1 if at least one data bit is read from the memory incorrectly, where E is greater than the number of bits the method is intended to correct.

3. A memory module (105) according to claim 1, wherein the check bit circuitry (120, 130) computes the check bits using XOR gates on unique subsets of the data bits.

4. A memory module (105) according to claim 3, wherein each of the data bits is used in at least E of the first set of partial parity check bits, where E is greater than a number of bit errors the method is intended to correct.

5. A memory module (105) according to claim 1, wherein the syndrome is capable of indicating one of the following results: no errors, one data bit error, one check bit error, one data bit err and one check bit error, two data bit errors, and two check bit errors.

6. A memory module (105) according to claim 1, further comprising:
correction vector circuitry (145) to generate a correction vector from the syndrome value; and
a second XOR gate (135) to correct the data bits.

7. A memory module (105) according to claim 6, wherein the correction vector circuitry (145) includes a two-level logic gate structure to generate the correction vector.

8. A system, comprising:
a computer (405);
a memory (105) in the computer (405), the memory (105) including:
storage (115) for data bits;
storage (125) for check bits;
check bit circuitry (120, 130) to compute the check bits from the data bits; and
an XOR gate (140) to compute a syndrome from the check bits,
wherein the syndrome is capable of identifying and correcting at least two bit errors.

9. A system according to claim 8, wherein the syndrome includes at least E bits set to 1 if at least one data bit is read from the memory (105) incorrectly, where E is greater than the number of bits the method is intended to correct.

10. A system according to claim 8, wherein the check bit circuitry (120, 130) computes the check bits using XOR gates on unique subsets of the data bits.

11. A system according to claim 10, wherein each of the data bits is used in at least E of the first set of partial parity check bits, where E is greater than a number of bit errors the method is intended to correct.

12. A system according to claim 8, wherein the syndrome is capable of indicating one of the following results: no errors, one data bit error, one check bit error, one data bit err and one check bit error, two data bit errors, and two check bit errors.

13. A system according to claim 8, further comprising:
correction vector circuitry (145) to generate a correction vector from the syndrome value; and
a second XOR gate (135) to correct the data bits.

14. A system according to claim 13, wherein the correction vector circuitry (145) includes a two-level logic gate structure to generate the correction vector.

15. A method for performing partial parity error correction, comprising:
receiving (505) a set of data bits;
computing (510), using check bit circuitry, a first set of partial parity check bits using the data bits;
storing (515) the data bits and the partial parity check bits in memory (105);
reading (520) the data bits from the memory (105);
computing (525) a second set of partial parity check bits using the read data bits;
XORing (530) the first set of partial parity check bits with the second set of partial parity check bits to produce a syndrome; and
using (535) the syndrome to correct any bit errors,
wherein the syndrome is capable of identifying and correcting at least two bit errors.

16. A method according to claim 15, wherein the syndrome includes at least E bits set to 1 if at least one data bit is read from the memory (105) incorrectly, where E is greater than the number of bits the method is intended to correct.

17. A method according to claim 15, wherein computing (510), using check bit circuitry, a first set of partial parity check bits using the data bits includes XORing (615) a unique subset of the data bits to compute each of the first set of partial parity check bits.

18. A method according to claim 17, wherein each of the data bits is used in at least E of the first set of partial parity check bits, where E is greater than a number of bit errors the method is intended to correct.

19. A method according to claim 15, wherein the syndrome is capable of indicating one of the following results: no errors, one data bit error, one check bit error, one data bit err and one check bit error, two data bit errors, and two check bit errors.

20. A method according to claim 15, wherein using (535) the syndrome to correct any bit errors includes:
generating (705) a correction vector from the syndrome value; and
XORing (715) the data bits with the correction vector.
